(19) United States
(12) Patent Application Publication
(10) Pub. No.: US 2025/0062695 A1
(43) Pub. Date: Feb. 20, 2025

(54) TECHNIQUES TO DETECT AN INDUCTOR-OPEN CONDITION IN VOLTAGE REGULATORS

(71) Applicant: TEXAS INSTRUMENTS INCORPORATED, Dallas, TX (US)

(72) Inventors: Rohit Narula, Bangalore (IN); Vikram Gakhar, Bangalore (IN); Preetam Tadeparthy, Bangalore (IN); Nischal R., Bangalore (IN)

(21) Appl. No.: 18/621,376

(22) Filed: Mar. 29, 2024

(30) Foreign Application Priority Data
Aug. 18, 2023 (IN) 202341055364

(51) Int. Cl. H02M 3/335; G01R 19/165

(52) U.S. Cl. CPC H02M 3/335; G01R 19/16571

(57) ABSTRACT

Some examples relate to a circuit including a plurality of input pins, a plurality of output pins, a pulse width modulated (PWM) controller, and an inductor-open detection circuit. The PWM controller has a plurality of inputs and a plurality of outputs. The plurality of inputs of the PWM controller are coupled to the plurality of input pins, and the plurality of outputs of the PWM controller are coupled to the plurality of output pins. The inductor-open detection circuit has an input coupled to a pin of the plurality of input pins, and has an output coupled to the PWM controller.

### BACKGROUND

Voltage regulators (e.g., direct current (DC)-to-DC converters, alternating current (AC)-to-AC converters, or the like) and analog-to-digital converters (ADCs), among other components, are widely used in modern electronics. Generally, computing devices rely upon voltage regulators to receive power. Voltage regulators generate a consistent output voltage based on an input voltage.

### SUMMARY

Some examples relate to a circuit including a plurality of input pins, a plurality of output pins, a pulse width modulated (PWM) controller, and an inductor-open detection circuit. The PWM controller has a plurality of inputs and a plurality of outputs. The plurality of inputs of the PWM controller are coupled to the plurality of input pins, and the plurality of outputs of the PWM controller are coupled to the plurality of output pins. The inductor-open detection circuit has an input coupled to a pin of the plurality of input pins, and has an output coupled to the PWM controller.

In another examples a voltage regulator includes a voltage input terminal and a voltage output terminal. The voltage regulator includes a power stage, a transformer, a pulse width modulation (PWM) controller, and an inductor-open detection circuit. The power stage has an input terminal and an output terminal, and the input terminal of the power stage is coupled to the voltage input terminal of the voltage regulator. The transformer has a primary winding and a secondary winding. The primary winding has a first terminal and a second terminal, and the secondary winding has a first terminal and a second terminal. The first terminal of the primary winding is coupled to the output terminal of the power stage, and the second terminal of the primary winding is coupled to the voltage output terminal of the voltage regulator. The PWM controller includes an input and an output. The input of the PWM controller is coupled to the transformer, and the output of the PWM controller is coupled to the input terminal of the power stage. The inductor-open detection circuit has an input and an output, the input of the inductor-open detection circuit is coupled to the output of the power stage or to the transformer. The output of the inductor-open detection circuit is coupled to the PWM controller.

Furthermore, another example relates to a method. The method involves regulating, by a circuit, an output voltage during a direct current (DC)-to-DC conversion mode by providing an integer number, N, of pulse width modulated (PWM) pulses during a time period, the N PWM pulses having N respective phase offsets that are spaced at approximately 360/N degrees from one another over the time period. The method also involves detecting, by the circuit, a fault condition during a fault detection mode by providing a single PWM pulse to trigger a current signal. The method also involves providing, by the circuit, a fault signal in response to whether a pulse length or a pulse slope magnitude of a falling edge of the current signal exceeds a pulse length threshold or a pulse slope threshold which is indicated by the fault condition.

### BRIEF DESCRIPTION OF THE DRAWINGS

FIG. 1 is an example schematic showing a trans-inductance voltage regulator (TLVR) circuit including a control circuit having an inductor-open detection circuit.

FIG. 2 is an example schematic showing a TLVR circuit and showing various pins of the power stages and control circuit, wherein power stages of the TLVR circuit include ammeters and transistors.

FIG. 3A is a timing diagram of a TLVR circuit illustrating an example of how DC-to-DC conversion is carried out using pulse-width modulated (PWM) signals, and how an inductor-open condition is detected and used to trigger shutdown of the PWM signals.

FIG. 3B is a timing diagram of the TLVR circuit illustrating how a current amplitude of the output current can change in time during DC-to-DC conversion to maintain an output voltage of the TLVR circuit at a substantially constant level.

FIG. 4 is an example schematic showing another TLVR circuit, wherein the inductor-open detection circuit is implemented as a digital application specific integrated circuit (ASIC) that includes a counter.

FIG. 5 is a timing diagram consistent with FIG. 4's TLVR circuit.

FIG. 6 is an example schematic showing another TLVR circuit, wherein the inductor-open detection circuit is implemented as a digital ASIC that includes a slew rate detector.

FIG. 7 is a timing diagram consistent with FIG. 6's TLVR circuit.

FIG. 8 is an example schematic showing another TLVR circuit, wherein the inductor-open detection circuit is implemented as an analog integrated circuit.

FIG. 9 is an example schematic showing another TLVR circuit, wherein the inductor-open detection circuit is implemented executable instructions running on a microcontroller.

FIG. 10 is an example flow chart showing a method for detecting an inductor-open condition in a voltage regulator.

FIG. 11 is another example flow chart showing a method for detecting an inductor-open condition in a voltage regulator.

### DETAILED DESCRIPTION

A voltage regulator is an electrical circuit that receives an input voltage and delivers a substantially constant output voltage in response to the input voltage. A Trans-inductor Voltage Regulator (TLVR) circuit is one type of voltage regulator. A TLVR circuit uses multiple inductors (e.g., transformers) that are arranged in series to store magnetic energy. The series inductors enable fast transient response for the voltage regulator. However, during operation, changes in the amount of current flowing through the inductors can lead to changes in electromagnetic force (EMF), and hence cause vibrations, on the inductors. These vibrations, as well as environmental conditions, can lead to an electrical disconnect (e.g., an “open”) between the inductors, which can cause device failure and/or dangerous conditions for the end user. Accordingly, various examples of the present description are related to voltage regulator control circuits that include an inductor-open detection circuit. The inductor-open detection circuit monitors signals from the voltage regulator and reports a fault signal when an electrical disconnect occurs. For example, when one of the inductors arranged in series becomes disconnected from the other inductors in the voltage regulator, the fault signal can be activated.

Although voltage regulators are illustrated herein in the form of TLVR circuits, other voltage regulators of this description can include other types of DC-to-DC converter or even can include AC-to-DC converters. For instance, some voltage regulators of this description can continuously step-down or “buck” the input voltage to the output voltage (e.g., as described below). However, other voltage regulators of this description can continuously step-up or “boost” the input voltage to the output voltage, or can even change between stepping-up and stepping-down the input voltage to the output voltage at different times (so called “buck/boost” converters).

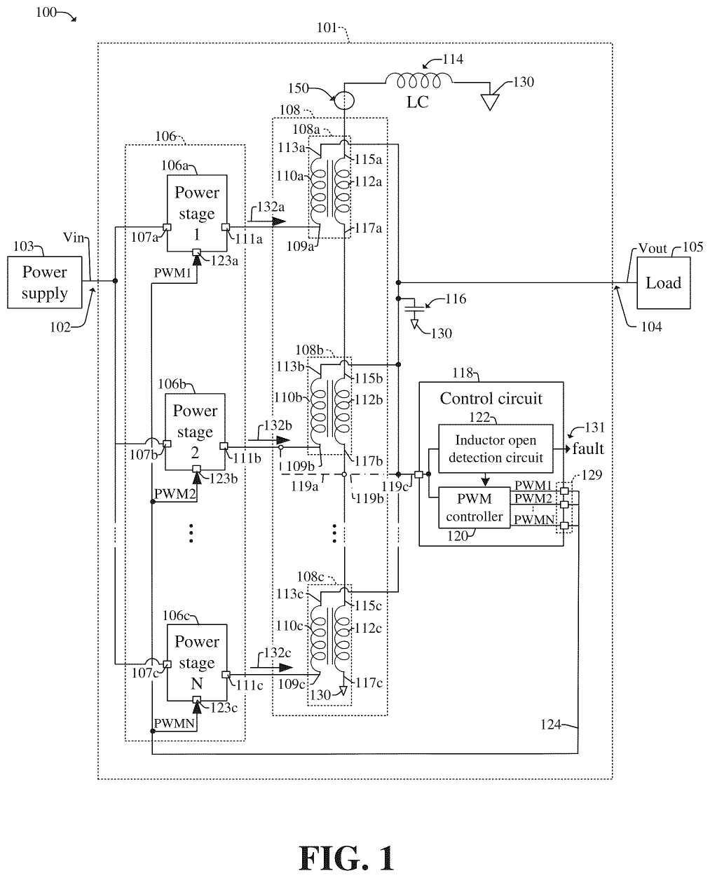

FIG. 1 depicts an electronic system 100 according to some examples. The electronic system 100 includes a voltage regulator 101 arranged between a power supply 103 and a load 105. The voltage regulator 101 has a voltage input terminal 102 coupled to an output of the power supply 103. The voltage regulator 101 also has a voltage output terminal 104 coupled to an input of the load 105. For example, the power supply 103 can be a battery, such as a car battery, and the load 105 can be an integrated circuit, such as an engine control unit, audio module for a vehicle, lighting control unit, data center servers, or enterprise Ethernet switches and routers, among others.

The voltage regulator 101 includes N power stages 106 and N transformers 108, where N is any positive integer. Thus, the power stages 106 include a first power stage 106a, second power stage 106b, . . . , and an Nth power stage 106c. Similarly, the transformers 108 include a first transformer 108a, second transformer 108b, . . . , and an Nth transformer 108c. Each of the transformers 108 has a primary winding and a secondary winding, which are wrapped around a core of that transformer. Thus, the first transformer 108a has a first primary winding 110a and a first secondary winding 112a; second transformer 108b has a second primary winding 110b and a second secondary winding 112b, and an Nth transformer 108c has an Nth primary winding 110c and a Nth secondary winding 112c. A compensation inductor 114, an output capacitor 116, and a control circuit 118 are also present. The control circuit 118 includes a PWM controller 120 and an inductor-open detection circuit 122, which are operably coupled.

The power stages 106a-106c have respective inputs 107a-107c coupled to the power supply 103, and have respective control inputs 123a-123c coupled to the control circuit 118. The power stages 106a-106c also have respective outputs 111a-111c coupled to first terminals 109a-109c, respectively, of the primary windings 110a-110c, respectively. The primary windings 110a-110c, respectively, have second terminal 113a-113c, respectively coupled to the voltage output terminal 104 of the voltage regulator. The first terminal 115a of the first secondary winding 112a is coupled to a first terminal of the compensator inductor 114. The compensator inductor 114 has a second terminal connected to ground 130. A second terminal 117a of the first secondary winding 112a is coupled to a first terminal 115b of the second secondary winding 112b. The second terminal 117b of the second secondary winding 112b is coupled to a first terminal of a next secondary winding. The first terminal 115c of the Nth secondary winding 112c is coupled to a second terminal of the (N−1)th secondary winding, and a second terminal 117c of the Nth secondary winding 112c is connected to ground 130. The input of the PWM controller 120 and/or inductor-open detection circuit 122 can be coupled to the output of one or more of the power stages 106 (see e.g., line 119a) and/or can be coupled to the primary or secondary windings of one or more of the transformers 108 (see e.g., lines 119b, 119c). The PWM controller 120 has an output that is coupled to respective inputs 107a-107c of the power stages 106a-106c, respectively, via a feedback path 124.

As appreciated in some aspects of the present description, in some circumstances the compensation inductor 114 (and/or other inductors of transformers 108) can become electrically disconnected (e.g., as shown by an open 150), due to vibrations, environmental conditions, or other conditions. Therefore, in some examples, the inductor-open detection circuit 122 monitors an output of one or more of the power stages 106 and/or a terminal of one or more of the transformers 108 to detect when an inductor-open condition is present. If an inductor-open condition is present, then the inductor-open detection circuit 122 can activate a fault signal 131. In response to the fault signal 131 being activated, the PWM controller 120 can deactivate PWM signals on output pins 129, thereby deactivating the power stages 106 until the fault signal 131 is repaired. This deactivation causes the power stages to refrain from allowing current to pass from the power supply 103 to the load 105. The deactivation signal may be a constant low value (e.g., low voltage) or a constant high value (e.g., high voltage) depending on the polarity of various switching elements. Further, the fault signal 131 can trigger an audio, visual, or other sensory queue indicating that the fault condition has been detected. For example, a flashing light, a check-engine light, some other dashboard/visual warning, a voice message, an email, a text message, or another warning can be provided to notify a user or repair person of the fault condition. Thus, by detecting the fault condition, the inductor-open detection circuit 122 can mitigate the impact of potentially dangerous conditions for the end user of the electronic system 100.

In some examples, the control circuit 118 is an integrated circuit, and the power stages 106a-106c are separate, discrete integrated circuits. The transformers 108a-108c can also be discrete components in some examples, and 106, 108, 114, and 118 can be arranged on a printed circuit board (PCB) or other package and can be operably coupled by conductive traces on the PCB. The feedback path 124 can be an N-bit bus or N pins including N separate lines/wires that extend in parallel with one another to connect respective output pins 129 of the control circuit 118 to respective control pins 123a-123c of the power stages 106a-106c. In other examples, the feedback path 124 can use fewer than N lines/wires, and control signals can be transmitted in serial (e.g., over different frequencies or in different time windows) over the feedback path 124. In other examples, the entire voltage regulator 101 can be on a single integrated circuit, or can be on separate integrated circuit die stacked over one another and/or adjacent to one another in a packaged integrated circuit, such as a so-called three-dimensional integrated circuit package. In still other cases, the illustrated components of FIG. 1 can be divided other ways among multiple integrated circuits and/or discrete devices, though the illustrated implementation offers good tradeoffs of costs, manufacturing reliability, and compatibility with real-world systems. Further, while a “pin” can be interpreted as an external node of an integrated circuit, connection points illustrated and described as “pins” herein can also be internal nodes of a packaged integrated circuit and/or die in other examples.

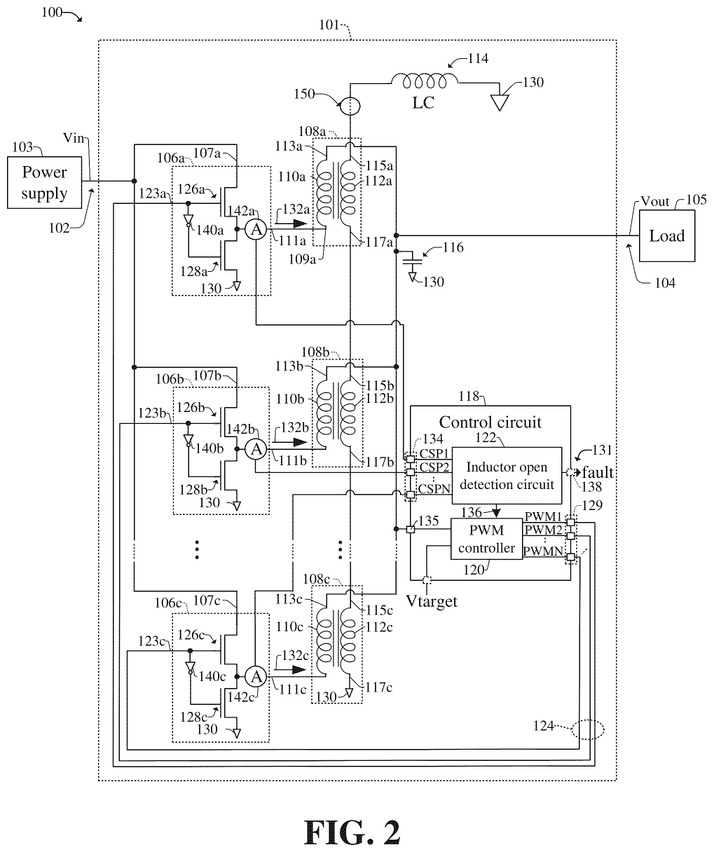

FIG. 2 illustrates another example of a voltage regulator 101 according to some aspects of this description. The same reference numbers from FIG. 1 are used in FIG. 2 to designate the same or similar (functionally and/or structurally) features, and this also carries through to subsequent FIGS. as well. For example, FIG. 2 includes power stages 106a-106a, transformers 108a-108c, and control circuit 118, consistent with FIG. 1. FIG. 2 also shows more details for some components, such as for the power stages, though these details do not limit the scope of FIG. 1.

In FIG. 2's example, the control circuit 118 includes a plurality of input pins 134 that are coupled to an input of the inductor-open detection circuit 122. Each of these input pins may be referred to as a current sense pin (CSP). These CSP pins (and/or another pin 135—which can be coupled to the voltage output terminal 104) may also be coupled to an input of the PWM controller 120. The control circuit 118 also includes a plurality output pins 129 coupled to an output of the PWM controller 120. The inductor-open detection circuit 122 also has an output coupled to an input of the PWM controller 120 (see line 136), and on which the fault signal 131 can be sent. The inductor-open detection circuit 122 can optionally provide the fault signal 131 on a pin 138 of the control circuit. The terms “input” and “output” for the pins can also include pins that are bi-directional, so an input pin can also act as an output pin (and vice versa) in some examples.

FIG. 2 also illustrates that the power stages 106 (e.g. 106a-106c) can each include first and second transistors 126 (e.g. 126a-126c), 128 (e.g. 128a-128c), an inverter 140 (e.g. 140a-140c), and an ammeter 142 (e.g. 142a-142c). For example, first power stage 106a includes first and second transistors 126a, 128a, first inverter 140a, and first ammeter 142a; second power stage 106b includes first and second transistors 126b, 128b, second inverter 140b, and second ammeter 142b; and Nth power stage 106c includes first and second transistors 126c, 128c, inverter 140c, and Nth ammeter 142c. The first and second transistors each include a first terminal (e.g., source/drain), a second terminal (e.g., drain/source), and control terminal (e.g., gate). Each inverter 140 has an input that is coupled to the control terminal of each power stage and that is coupled to a gate of the first transistor 126. The output of each inverter 140 is coupled to the gate of the second transistor 128, such that the first and second transistors 126, 128 operate in complementary fashion. An input terminal of each ammeter 142 is coupled to an output terminal of the first and second transistors 126, 128, and an output terminal of each ammeter 142 is coupled to the input of the inductor-open detection circuit 122.

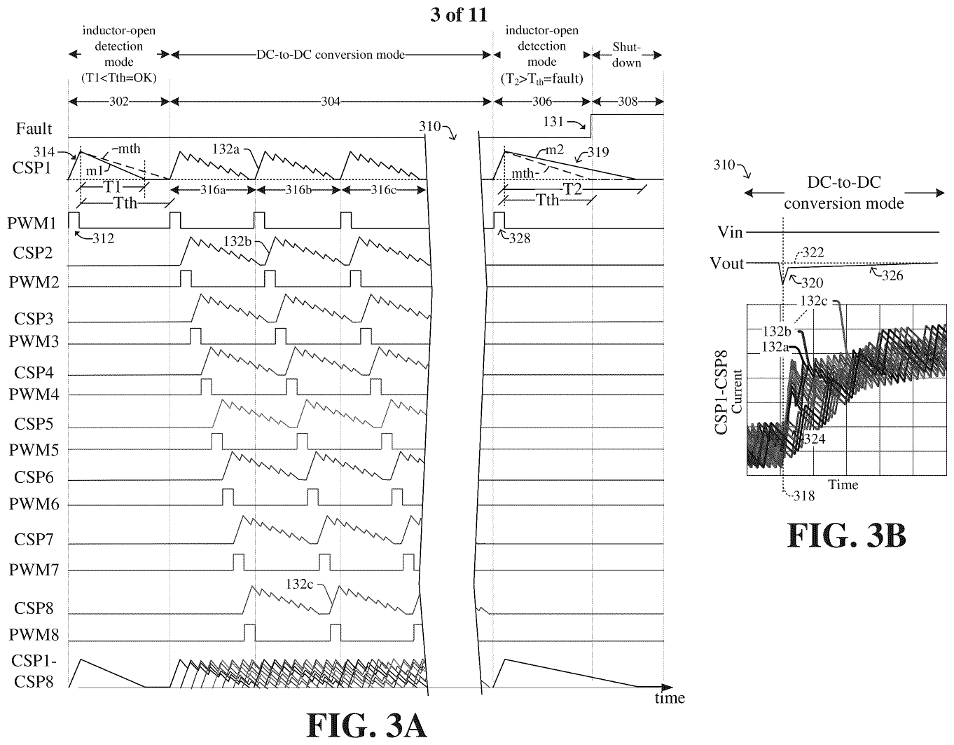

The power stages 106a-106c allow current to pass from the power supply 103 to the load 105 based on the PWM signals (PWM1, PWM2, . . . , PWMN) from the PWM controller 120. The power stages 106a-106c are configured to be switched at different times such that at any point in time, current is flowing from the power supply 103 to the load 105 through a single power stage 106. The other power stages that are not active will allow current to flow from ground 130 to the load 105. FIGS. 3A-3B illustrate example operation of the voltage regulator 101 of FIG. 1 or FIG. 2. During operation, the voltage regulator 101 can change between an inductor-open detection mode (see times 302, 306), a DC-to-DC conversion mode (see time 304), and a shutdown mode (see time 308). In the example of FIGS. 3A-3B, the voltage regulator has N=8 power stages and N=8 transformers, such that eight PWM control signals PWM1, PWM2, . . . , PWM8 drive eight phase currents (or voltages corresponding to the phase currents) 132a, 132b, . . . , 132c on eight pins CSP1, CSP2, . . . , CSPN, respectively. The inductor-open detection mode may also be referred to as a fault detection mode.

Briefly, during inductor-open detection mode of time 302, a single PWM pulse 312 is provided on only a single PWM output pin (e.g., PWM1). The PWM pulse 312 couples the first terminal of the first transistor (e.g., 126a) to Vin, thereby triggering a current pulse 314 on a corresponding current sensing pin (e.g., CSP1). The current pulse 314 decreases after the PWM pulse 312 according to the following equation:

$$\frac{di}{dt} = \frac{- N * {v}_{out}}{{L}_{c}} + \frac{- {v}_{out}}{{L}_{m}}$$

Where i is the current measured by CSP1, t is time, N is the number of phases, L_{C} is the inductance of the compensator inductor 114, vₒᵤₜ is the output voltage to the load 105, and L_{M} is the inductance of the primary winding 110a.

In some cases, this inductor-open detection mode at time 302 can occur during a boot sequence of the control circuit 118. The inductor-open detection circuit 122 determines whether a measured pulse length (T1) of a falling edge of the current pulse 314 exceeds a pulse length threshold (Tth), or alternatively whether or a measured pulse slope (m1) has a magnitude that is less a pulse slope threshold (mth). The inductor-open detection mode at time 302 occurs while all other control signals (PWM2, PWM3, . . . , PWM8) are off, which also means that there is minimal current on the seven other pins (CSP2, CSP3, . . . , CSPN). Thus, giving an advantage because there is a reduction in noise while the pulse length is being measured. The pulse length threshold (Tth) and/or pulse slope threshold (mth) is set such that if the compensation inductor 114 is “open”, or is disconnected, then the measured pulse length exceeds the pulse length threshold (and/or the pulse slope has a slope magnitude that is less that is than the pulse slope threshold). In contrast, if the compensation inductor 114 is properly connected, then the pulse length is less than the pulse length threshold (and/or the pulse slope has a slope magnitude that is greater than the pulse slope threshold). For example, in time 302, current pulse 314 has a measured pulse length of T1, which is measured from the peak of the current pulse 314 to the time when the current pulse 314 returns back to its initial current value. Here, T1 is less than the pulse length threshold Tth, so the inductor-open detection circuit 122 does not activate the fault signal during time 302. Accordingly, when there is no fault condition, the voltage regulator continues to DC-to-DC conversion mode.

In the DC-to-DC conversion mode of time 304, the PWM controller activates N=8 PWM pulses (PWM1-PWM8) during a time period (e.g., time period 316a). The N PWM pulses having N respective phase offsets that are spaced at 360/N degrees from one another over each of the N time periods. During time 304 of DC-to-DC conversion mode, the voltage regulator monitors the output voltage Vout. A zoomed in window showing the voltage regulation can be seen during the blocked out period 310. At time 318 in FIG. 3B, the load circuit increases its power demands (e.g., turns on or “wakes” up from a low-power/sleep state), resulting in a brief time when Vout decreases or “dips” below a lower voltage threshold 322. In response to this decrease in Vout, the PWM controller can change the PWM control signals provided to the power stages to increase the magnitude of the phase currents driven into the primary windings (see 324). Because of the mutual inductive couplings in the transformers, this increase in phase currents into the primary windings also increases the output current from secondary windings of the transformers, thereby increasing the output voltage Vout on the voltage output terminal 104 and restoring Vout to its initial voltage level (see 326). The mutual inductive coupling between the transformers allows a fast transient response 320 such that most of the voltage is recovered in a small amount of time. Although not illustrated, if Vout exceeds an upper voltage threshold, the PWM controller can also “tune” the PWM control signals to decrease the phase currents and correspondingly decrease the output voltage Vout. Thus, the PWM controller 120 continuously monitors the output voltage Vout and provides PWM control signals to maintain a substantially constant output voltage, even with changes in power demands of the load circuit and changes in Vin. Alternatively, rather than being set to a constant output voltage, Vout can optionally track a target voltage (Vtarget), wherein Vtarget can change in time based on a predetermined function and/or a time-varying control function.

At time 306, after DC-to-DC conversion mode at time 304 and/or at when the control circuit boots up again, the inductor-open detection mode at time 306 is again carried out. In this time 306, the PWM pulse 312 is again provided on only a single PWM output pin (e.g., PWM1) and the PWM pulse 328 triggers the current pulse 316 (e.g., 316a-316c). In contrast to time 302, during time 306 the compensating inductor is now “open”, which causes the pulse length (T2) on the falling edge of the current pulse 316 to exceed the pulse length threshold (Tth) according to the following equations:

$$\begin{matrix}\frac{di}{dt} = \frac{- {v}_{out}}{{L}_{m}} \\ T 2 = ( 1 - \frac{{v}_{out}}{{v}_{in}} ) {T}_{sw} \\ T 1 = T 2 + {T}_{y} \\ {T}_{y} = \frac{( 1 - N ) {T}_{sw}}{{L}_{c} ( \frac{1}{{L}_{m}} + \frac{N}{{L}_{C}} )} \\ {T}_{th} = ( T 1 + T 2 ) / 2\end{matrix}$$

Alternatively, the pulse slope magnitude (m2), shown by 319, on the falling edge of the current pulse 316 is less than the pulse slope threshold (mth). Because of this, the inductor-open detection circuit 122 activates the fault signal 131, and enters a shutdown mode at time 308. During the shutdown mode, the PWM controller, which learns of the fault condition from the inductor-open detection circuit, continuously deactivates the PWM signals in response to activation of the fault signal. Accordingly, the PWM signals are deactivated until the fault is repaired or otherwise reset. Thus, by activating the fault condition, the inductor-open detection circuit 122 can mitigate the impact of potentially dangerous conditions.

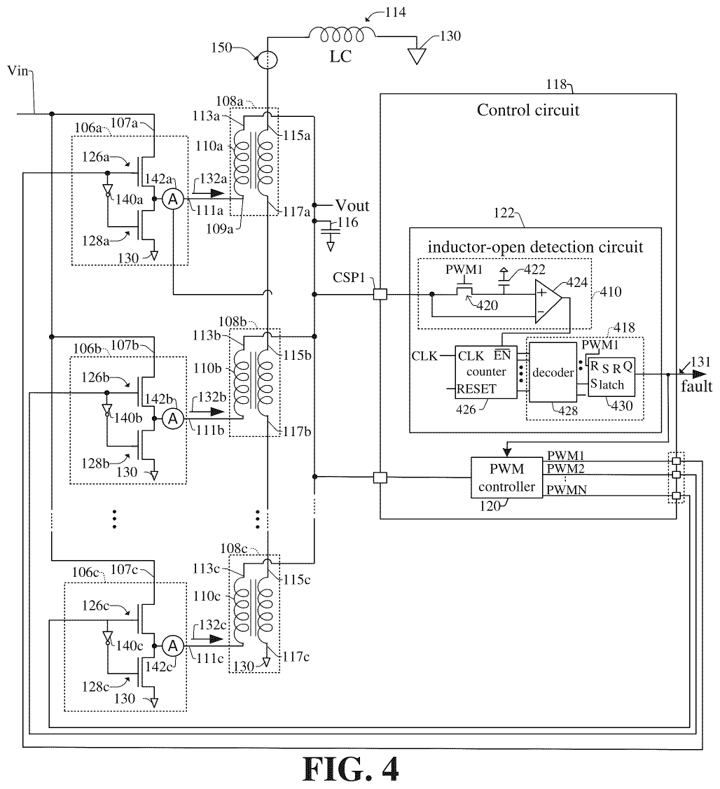

FIG. 4 shows an example where the inductor-open detection circuit 122 manifests as a digital ASIC. In this example, the inductor-open detection circuit 122 includes a trigger circuit 410, a counter 426, and a comparison circuit 418. The trigger circuit 410 can include a switch 420, a charge storage capacitor 422, and an operational amplifier 424. The comparison circuit 418 can include a decoder 428 and a latch 430. The counter 426 has an input coupled to the output of the trigger circuit 410, which is coupled to output of ammeter 142a. The comparison circuit 418 has an input coupled to an output of the counter 426. The counter 426 counts a number of clock cycles that it takes for a current signal (which may be represented as a voltage on CSP1) from the ammeter 142a to decrease from a peak current value to a threshold current value. The ammeter 142a may provide an amplitude of the current. The comparison circuit 418 compares the number of clock cycles to a predetermined count threshold, and triggers a fault signal 131 in response to the comparison.

The switch 420 has a first terminal, a second terminal, and a control terminal. The first terminal is connected to CSP1, and the second terminal is connected to a first terminal of the operational amplifier 424. The control signal of the switch 420 is coupled to PWM1. The charge storage capacitor 422 has a first terminal connected to the first terminal of the operational amplifier 424 and has a second terminal connected to ground. An output of the operational amplifier 424 is connected to an enable terminal, or enable input, of the counter 426. The counter 426 has a first terminal, or clock input, connected to a clock, and second/reset terminal connected to PWM 1. Output terminals of the counter 426 are connected to input terminals of the decoder 428. The decoder 428 also has output nodes, such that at least one of the output nodes is connected to a first terminal of the latch 430. The latch 430 has a second terminal connected to PWM1, and an output of the latch 430 provides the fault signal 131.

During operation, the switch 420 intermittently connects CSP1 to the charge storage capacitor 422 to develop a voltage indicative of the current on CSP1. Thus, when the switch 420 is subsequently opened, the operational amplifier 424 compares the voltage stored on the charge storage capacitor 422 to the present voltage on CSP1. The voltage stored on the charge storage capacitor 422 may be understood to be a reference signal. When the present voltage on CSP1 is larger than the voltage stored on the charge storage capacitor 422, the operation amplifier 424 forces the enable terminal of the counter 426 to be low, so that the counter 426 is enabled. Thus, the switch 420, the charge storage capacitor 422, and the operation amplifier 424 function to enable or disable the counter 426. The counter 426 operates by incrementing a stored binary value whenever a clock pulse is received from the CLK. The counter 426 further has a reset pin connected to PWM1. Thus, the counter 426 is configured to measure a time between the falling edge of PWM 1 and a cross over between a present value of CSP1 and a previous value of CSP1, which is stored in the charge storage capacitor 422. The decoder 428 performs some logic operation of AND among the inputs received from the counter 426. This allows the decoder to indicate whether the measured count value is greater than a predetermined pulse length threshold. The latch 430 the stores a result and outputs the fault signal 131 to indicate whether the measured count value is greater than a predetermined pulse length threshold. The latch 430 can be reset during each cycle by have the reset pin connected to PWM 1.

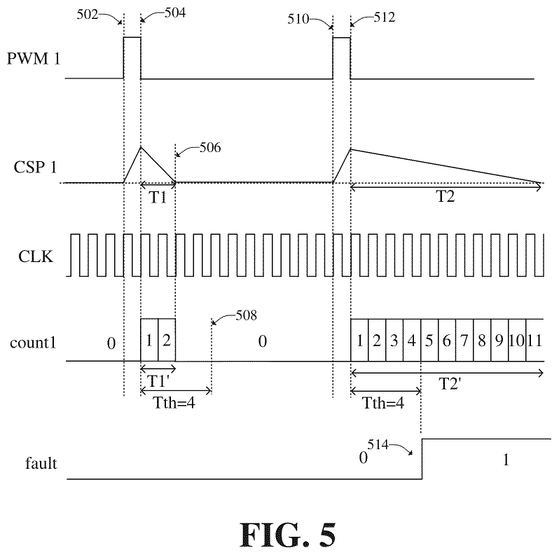

FIG. 5 is a timing diagram of an example operation of FIG. 4's digital ASIC including a counter. This timing diagram shows a signal for PWM1, CSP1, CLK, an internal count, and the fault signal. This timing diagram points out times 502, 504, 506, 508, 510, 512, and 514. At 502, a rising edge of PWM1 occurs. At 504, a falling edge of the PWM pulse to PWM1 occurs. At 508, a time threshold is shown. At 510, a second rising edge of PWM1 occurs. At 512, a second falling edge to PWM1 occurs. At 514, a fault signal changes values.

The CSP1 waveform shows an increasing current while PWM1 is on between times 502 and 504, due to first transistor 126a being “on” during this time. At 502, the switch 420 is activated to be in a closed position for a short period of time, so that the value of CSP 1 around time 502 is stored on the charge storage capacitor 422 and provided to the positive pin of the operational amplifier 424. After 504, the CSP 1 waveform shows a decreasing current because the primary winding 110a is losing energy. Between times 502 and 504 the negative pin of the operational amplifier 424 has a rising value because of the rising CSP 1 value. The output of the operational amplifier 424 is negative from time 502 to 506 because CSP 1 is larger between time 502 and 506 compared to the value of CSP 1 around time 502, thus, enabling the counter. The counter begins to count CLK pulses at time 504, which is the falling edge of the pulse, because while PWM1 is high, the counter 426 is reset. Thus, allowing the counter 426 to count the number of pulses for PWM1 to return to its starting value at 502 to measure the time T1 as T1′. The decoder 428 provides a logic AND among the counter 426 outputs, so that a specific time can be detected. This specific time may correspond to Tth. In this example, T1′ is less than the threshold time, Tth, which is shown at 508, so a fault is not indicated.

A second pulse occurs between 510 and 512 such that the CSP1 current increases during this time. After 512, the CSP1 current decreases. The operational amplifier 424 compares the value of CSP1 around time 510 to the value of CSP1 between 510 and 512, and the operational amplifier 424 outputs a low value to the counter 426. This low value enables the counter 426. The counter 426 begins to count once PWM1 goes low at time 512 because PWM1 is connected to the reset pin of the counter 426. Thus, allowing the counter 426 to count the CLK pulses and store time T2 as T2′. The decoder 428 provides some logical expression to the output of the counter 426 to detect if the time T2′ is equal to Tth. Once the time T2′ is equal to (and/or greater than) Tth, the latch 430 receives a high signal to its set pin, and outputs a fault at 514.

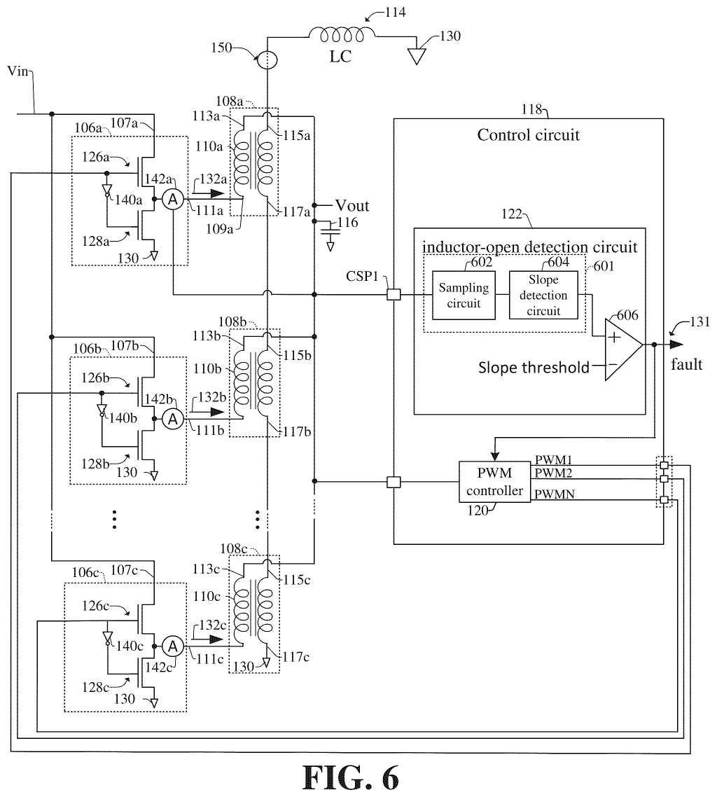

FIG. 6 shows an example of the inductor-open detection circuit 122 being implemented by means of slope detection. In this example, there is a slew rate circuit 601 that includes a sampling circuit 602 and a comparator 606. The sampling circuit 602 has an input and an output, and the slope detection circuit 604 has an input and an output. The comparator has a positive input, a negative input, and an output. The sampling circuit 602, slope detection circuit 604, and comparator 606 may be implemented in hardware (e.g., an ASIC), a field programmable gate array (FPGA), or with discrete components.

The input of the sampling circuit 602 is coupled to CSP1, and the output of the sampling circuit 602 is coupled to the input of the slope detection circuit 604. The output of the slope detection circuit 604 is coupled to the positive input of the comparator 606. The negative input of the comparator is connected to a reference indicating a slope threshold. The output of the comparator 606 is connected to fault signal 131.

The sampling circuit 602 may sample a pair of values from CSP1 with a known time interval between them, and provide these sampled values to the slope detection circuit 604. The slope detection circuit 604 may perform a calculation with the pair of values to determine a slope between them. The slope detection circuit 604 may provide a voltage representing the slope magnitude to the comparator 606. The comparator 606 compares the voltage representing the slope magnitude with the slope threshold and outputs a fault when the voltage representing the slope magnitude is less than the slope threshold.

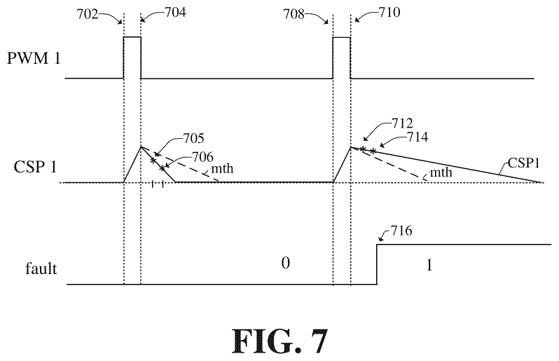

FIG. 7 shows how the slope detection in FIG. 6 may operate. FIG. 7 shows waveforms for PWM 1, CSP 1, and fault. FIG. 7 has callouts to times 702, 704, 708, 710, and 716. FIG. 7 also shows measured samples 706, 712, 714, and threshold slope mth.

At time 702, a rising edge of a first pulse to PWM 1 occurs. At time 704, a falling edge of the first pulse to PWM 1 occurs. At time 708, a rising edge of a second pulse to PWM 1 occurs. At time 710, a falling edge of the second pulse to PWM 1 occurs. At time 716, the fault signal changes value from 0 to 1, indicating a fault.

The measured samples 705, 706, 712, and 714 are sampled by the sampling circuit 602 and are used to calculate the slope magnitude of CSP 1. The slope magnitude calculation may be done by the slope detection circuit 604 receiving each pair of samples, such as 705 and 706 or 712 and 714, subtracting one sample of the pair from the other sample of the pair to define a difference, taking the absolute value of the difference, and then dividing the difference by a known time between the samples. This slope magnitude is compared to the slope threshold, mth, by the comparator 606. If the calculated slope magnitude is less than the slope threshold, mth, then the comparator 606 outputs a fault. For example, a fault is detected at 716 because the slope magnitude of CSP 1 calculated from the measured samples 712 and 714 is less than mth.

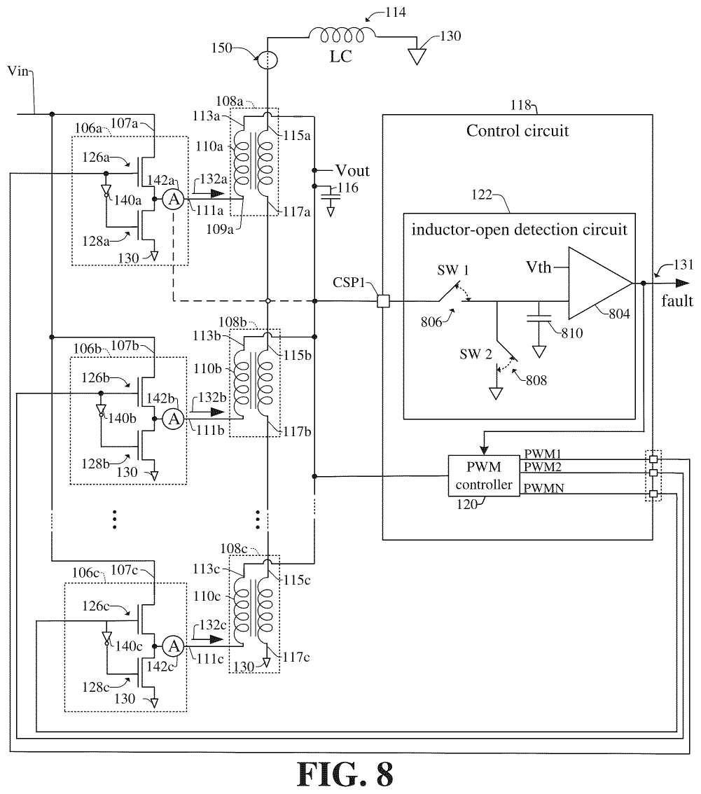

FIG. 8 shows an example where the inductor-open detection circuit 122 has an analog implementation. The circuit 122 has a first switch 806, a second switch 808, a capacitor 810, and a comparator 804. The first switch 806 may have a first terminal connected to CSP1, a second terminal connected to a first terminal of the second switch 808, and a control terminal. The second terminal of the first switch 806 is also coupled to a first terminal of the capacitor 810 and a first terminal of the comparator 804. The second switch 808 may have a second terminal connected to ground. The capacitor 810 may have a second terminal connected to ground. The comparator 804 may have a second terminal connected to a threshold voltage (Vth) and an output connected to fault terminal.

During operation, the first switch 806 closes to connect CSP1 to the capacitor 810. After the first switch 806 closes, the capacitor 810 begins to build up charge. After a period of time, the first switch 806 opens and the second switch 808 closes to discharge the capacitor 810. If the capacitor 810 built up a voltage larger than Vth during the time that the first switch 806 was closed, the comparator may change the output value from low to high or from high to low, indicating a fault. The control of the first switch 806 and the second switch 808 is configured to measure a combination of voltage and time from the CSP1 terminal.

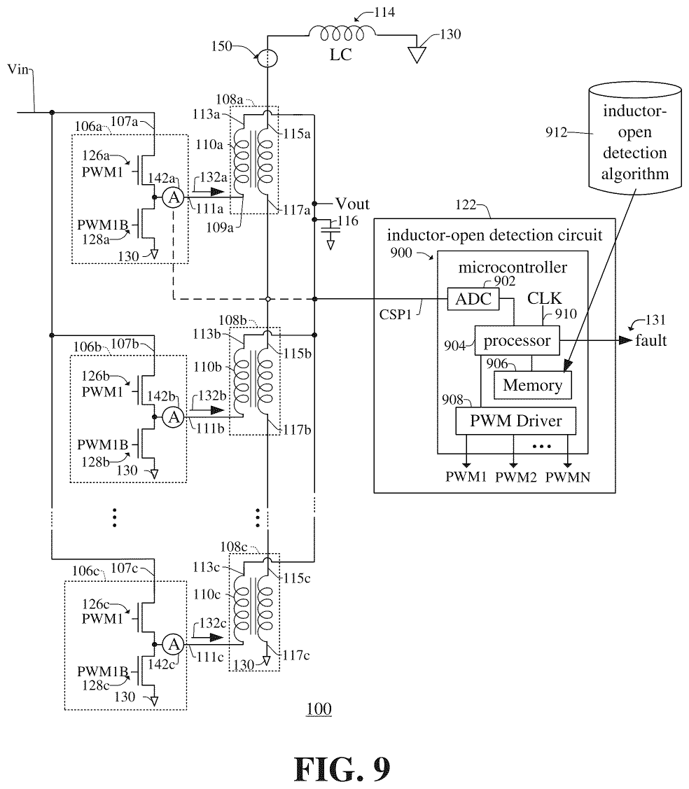

FIG. 9 shows another example of the inductor-open detection circuit 122. In this example, the inductor-open detection circuit may have a microcontroller 900. The microcontroller may have an analog-to-digital converter (ADC) 902, a processor 904, a memory 906, a PWM driver 908, and a clock 910 (CLK). The microcontroller may have a first terminal connected to CSP 1, a second terminal connected to fault, and a plurality of PWM output terminals used to control the transistors 126a-126c and transistors 128a-128c. The microcontroller may include processor-executable instructions 912, such as software, firmware, or hardcoded instructions, that measure a value from the CSP 1, count a number of clock cycles, and report a fault depending on a condition involving the counting of the number of clock cycles and/or a measurement of a slope magnitude of a current signal. Alternatively, the instructions 912 can measure a slope magnitude of CSP1 and compare that to a slope threshold. Further, because the microcontroller is controlling the PWM signals: PWM 1, PWM 2, PWM N, the microcontroller may change the pulse width or frequency of the PWM signals depending on if a fault is detected.

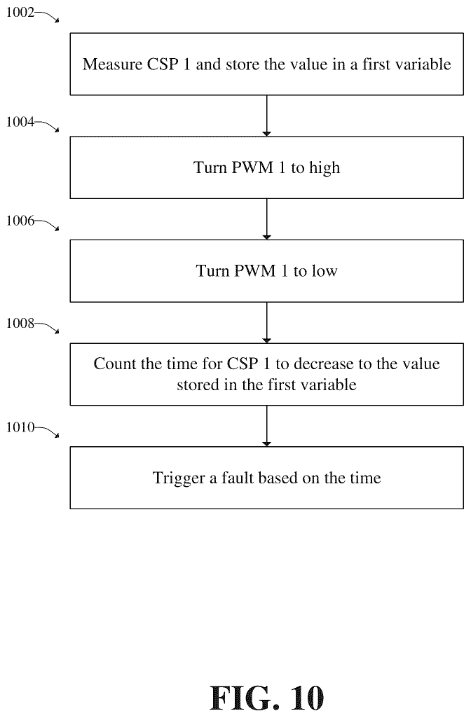

FIG. 10 shows a flowchart of a method implemented by the microcontroller. At step 1002, the microcontroller measures CSP1 and stores the value in a first variable. At step 1004, the microcontroller turns PWM 1 to high. At step 1006, the microcontroller turns PWM 1 to low. At step 1008, the microcontroller counts the time for CSP 1 to decrease to the value stored in the first variable, at step 1010, the microcontroller may trigger a fault based on a calculation involving the time.

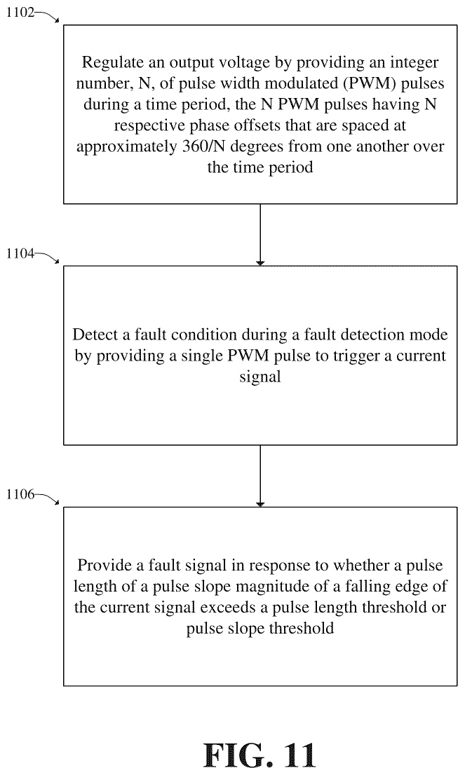

FIG. 11 shows a flowchart of a method implemented by the control circuit. At step 1102, the control circuit regulates an output voltage by providing an integer number, N, of pulse width modulated (PWM) pulses during a time period, the N PWM pulses having N respective phase offsets that are spaced at approximately 360/N degrees from one another over the time period. At step 1104, the control circuit detects a fault condition during a fault detection mode by providing a single PWM pulse to trigger a current signal. At step 1106, the control circuit provides a fault signal in response to whether a pulse length of a pulse slope magnitude of a falling edge of the current signal exceeds a pulse length threshold or pulse slope threshold.

The methods are illustrated and described above as a series of acts or events, but the illustrated ordering of such acts or events is not limiting. For example, some acts or events may occur in different orders and/or concurrently with other acts or events apart from those illustrated and/or described herein. Also, some illustrated acts or events are optional to implement one or more aspects or embodiments of this description. Further, one or more of the acts or events depicted herein may be performed in one or more separate acts and/or phases. In some embodiments, the methods described above may be implemented in a computer readable medium using instructions stored in a memory.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are illustrated and/or described herein, other transistors (or equivalent switching devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices described herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero. Modifications are possible in the described examples, and other implementations are possible, within the scope of the claims.

What is claimed is:

1. A circuit, comprising:
a plurality of input pins;
a plurality of output pins;
a pulse width modulated (PWM) controller having a plurality of inputs and a plurality of outputs, the plurality of inputs of the PWM controller coupled to the plurality of input pins and the plurality of outputs coupled to the plurality of output pins; and
an inductor-open detection circuit having an input coupled to a pin of the plurality of input pins and having an output coupled to the PWM controller.

2. The circuit of claim 1, wherein a plurality of PWM signals on the plurality of output pins are deactivated in response to a pulse length or a pulse slope magnitude of a falling edge of a waveform on the pin exceeding a pulse length threshold or a pulse slope threshold.

3. The circuit of claim 2, wherein the PWM controller is configured to operate in a DC-to-DC conversion mode and an inductor-open detection mode, wherein each of the plurality of PWM signals are switched during the DC-to-DC conversion mode, and less than all of the plurality of PWM signals are switched during the inductor-open detection mode.

4. The circuit of claim 1, wherein the inductor-open detection circuit is configured to selectively activate a fault signal in response to a pulse length or pulse slope magnitude of a falling edge of a waveform on the pin exceeding a pulse length threshold or pulse slope threshold.

5. The circuit of claim 4, wherein the PWM controller is configured to deactivate PWM signals on the output pins in response to activation of the fault signal.

6. The circuit of claim 1, wherein the inductor-open detection circuit comprises:
a trigger circuit having an input and an output; the input of the trigger circuit coupled to the pin;
a counter having a clock input, an enable input, and an output; the enable input is coupled to the output of the trigger circuit; and
a decoder having an input coupled and an output, the input of the decoder coupled to the output of the counter, and the output of the decoder coupled to the PWM controller.

7. The circuit of claim 6,
wherein the input of the trigger circuit is a first input and the trigger circuit is configured to receive a current amplitude on the first input;
wherein the counter is configured to increment a count value on the output of the counter while the current amplitude is greater than a reference signal; and
wherein the decoder is configured to output a fault signal when the count value exceeds a pulse length threshold.

8. The circuit of claim 1, wherein the inductor-open detection circuit comprises:
a slew rate circuit having an input and an output, the input of the slew rate circuit coupled to the pin; and
a comparison circuit having an input and an output, the input of the comparison circuit coupled to the output of the slew rate circuit and the output of the comparison circuit coupled to the PWM controller.

9. The circuit of claim 1, wherein the PWM controller is configured to operate in a DC-to-DC conversion mode and an inductor-open detection mode,
wherein during the DC-to-DC conversion mode, the PWM controller provides an integer number, N, of PWM pulses on the plurality of output pins, respectively, during N time periods, the N PWM pulses having phase offsets that are spaced at approximately 360/N degrees from one another for each time period; and
wherein during the inductor-open detection mode, a PWM pulse is provided on only a single PWM output pin and the PWM pulse triggers a current signal, and a fault signal is triggered based on whether a pulse length or a pulse slope magnitude of a falling edge of the current signal exceeds a pulse length threshold or pulse slope threshold.

10. A voltage regulator including a voltage input terminal and a voltage output terminal, the voltage regulator comprising:
a power stage having an input terminal and an output terminal, the input terminal of the power stage coupled to the voltage input terminal of the voltage regulator;
a transformer comprising a primary winding and a secondary winding, the primary winding having a first terminal and a second terminal and the secondary winding having a first terminal and a second terminal, the first terminal of the primary winding coupled to the output terminal of the power stage, the second terminal of the primary winding coupled to the voltage output terminal of the voltage regulator;
a pulse width modulation (PWM) controller including an input and an output, the input of the PWM controller coupled to the transformer, and the output of the PWM controller coupled to the input terminal of the power stage; and
an inductor-open detection circuit having an input and an output, wherein the input of the inductor-open detection circuit is coupled to the output of the power stage or to the transformer, and the output of the inductor-open detection circuit is coupled to the PWM controller.

11. The voltage regulator of claim 10, wherein the power stage further comprises:
an ammeter comprising an input terminal and an output terminal, wherein the input terminal of the ammeter is coupled to the output terminal of the power stage and the output terminal of the ammeter is coupled to the input of the inductor-open detection circuit.

12. The voltage regulator of claim 11, wherein the inductor-open detection circuit comprises:
a counter having an input coupled to the output of the ammeter, the counter configured to count a number of clock cycles for a current signal from the ammeter to decrease from a peak current value to a threshold current value; and
a comparison circuit coupled to an output of the counter, the comparison circuit configured to compare the number of clock cycles to a predetermined count threshold and trigger a fault signal in response to the comparison.

13. The voltage regulator of claim 11, wherein the inductor-open detection circuit comprises:
a slew rate circuit having an input coupled to the output of the ammeter, the slew rate circuit configured to determine a slope magnitude for a current signal from the ammeter between a peak current value and a threshold current value; and
a comparison circuit configured to compare the slope magnitude to a slope threshold and trigger a fault signal in response to the comparison.

14. The voltage regulator of claim 10, wherein the inductor-open detection circuit comprises:
a first switch having a first terminal, a second terminal, and a control terminal, the first terminal of the first switch coupled to the output of the power stage,
a capacitor having a first terminal and a second terminal, the first terminal of the capacitor coupled to the second terminal of the first switch, and
a comparator including a first terminal, a second terminal, and an output terminal, wherein the first terminal of the comparator is coupled to the second terminal of the capacitor, and the output terminal of the comparator is coupled to the PWM controller.

15. The voltage regulator of claim 10, wherein the power stage is a first power stage, the primary winding is a first primary winding, the secondary winding is a first secondary winding, and the transformer is a first transformer, the voltage regulator further comprising:
a second power stage comprising an input terminal and an output terminal, the input terminal of the second power stage coupled to the input terminal of the first power stage; and
a second transformer including a second primary winding and a second secondary winding, the second primary winding having a first terminal and a second terminal and the second secondary winding having a first terminal and a second terminal, the first terminal of the second primary winding coupled to the output terminal of the second power stage, the second terminal of the second primary winding coupled to the second terminal of the first primary winding.

16. The voltage regulator of claim 15, wherein the second terminal of the first secondary winding is coupled to the first terminal of the second secondary winding, and the voltage regulator further comprising:
a compensator inductor having a first terminal coupled to the first terminal of the first secondary winding.

17. A method, comprising:
regulating, by a circuit, an output voltage during a direct current (DC)-to-DC conversion mode by providing an integer number, N, of pulse width modulated (PWM) pulses during a time period, the N PWM pulses having N respective phase offsets that are spaced at approximately 360/N degrees from one another over the time period;
detecting, by the circuit, a fault condition during a fault detection mode by providing a single PWM pulse to trigger a current signal; and
providing, by the circuit, a fault signal in response to whether a pulse length or a pulse slope magnitude of a falling edge of the current signal exceeds a pulse length threshold or pulse slope threshold which is indicated by the fault condition.

18. The method of claim 17, wherein the N PWM pulses are received at N pins of an integrated circuit, respectively, and wherein the single PWM pulse is provided on only one of the N pins of the integrated circuit.

19. The method of claim 17, wherein detecting the fault condition comprises:
counting a number of clock cycles for the falling edge of the current signal to decrease from a peak current value to a threshold current value; and
activating the fault signal by comparing of the number of clock cycles to a predetermined count threshold.

20. The method of claim 17, wherein detecting the fault condition comprises:
determining a slope magnitude of the falling edge of the current signal; and
activating the fault signal by comparing the slope magnitude to a slope threshold.
